(19) United States
(12) Patent Application Publication
(10) Pub. No.: US 2023/0374647 A1
(43) Pub. Date: Nov. 23, 2023

(54) SUBSTRATE PROCESSING APPARATUS AND SUBSTRATE PROCESSING METHOD

(71) Applicant: CANON KABUSHIKI KAISHA, Tokyo (JP)

(72) Inventors: Masumi Itabashi, Yamato-shi (JP); Yasushi Kawasumi, Fujisawa-shi (JP); Etsuro Kishi, Sagamihara-shi (JP)

(21) Appl. No.: 18/358,135

(22) Filed: Jul. 25, 2023

Related U.S. Application Data
(62) Division of application No. 16/840,674, filed on Apr. 6, 2020.

(30) Foreign Application Priority Data
Apr. 24, 2019 (JP) 2019-083212

(51) Int. Cl. C23C 14/04; H01L 21/68; H10K 71/00; H10K 71/16

(52) U.S. Cl. CPC C23C 14/042; H01L 21/682; H10K 71/00; H10K 71/166

(57) ABSTRACT

A substrate processing apparatus includes a film forming chamber in which a film is formed on a substrate, and a movable member configured to support a mask or both the mask and the substrate in an internal space of the film forming chamber and be movable. Before the film is formed on the substrate, in a state in which the substrate conveyed to the internal space of the film forming chamber by a substrate conveying mechanism is separated from the mask supported by the movable member, the movable member moves so as to reduce an alignment error between the substrate and the mask and then supports the substrate. The movable member moves to a predetermined position after the substrate is supported by the movable member and before the substrate is taken out from the film forming chamber by the substrate conveying mechanism.

### CROSS-REFERENCE TO RELATED APPLICATIONS

This application is a divisional application of U.S. patent application Ser. No. 16/840,674, filed Apr. 6, 2020, which claims the benefit of Japanese Patent Application No. 2019-083212, filed Apr. 24, 2019. Both prior applications are hereby incorporated by reference herein in their entirety.

### BACKGROUND OF THE INVENTION

### Field of the Invention

The present invention relates to a substrate processing apparatus and a substrate processing method.

### Description of the Related Art

Research and development have been carried out to form a functional layer on a substrate to provide an element for an application corresponding to the functional layer. It is known that a light emitting element is formed by forming the functional layer as an organic or inorganic light emitting layer. On the other hand, a photoelectric conversion element can be formed by forming the functional layer as an organic or inorganic photoelectric conversion layer. In order to form these functional layers, a formation method such as a sputtering method or a CVD method suitable for the functional layer can be employed. A substrate is positioned to form the functional layer at a determined position. In addition, a mask is used to form the functional layer at a specific position. The mask is a member that limits a region in which the functional layer is formed. An operation of setting the relative position between the mask and the substrate to a predetermined relative position is called alignment.

Japanese Patent Laid-Open No. 2014-70242 (hereinafter PTL1) describes a vapor deposition apparatus in which after a substrate is placed in a preparation chamber, the inside of the preparation chamber is evacuated, the substrate is moved to a plasma processing chamber and cleaned therein, the substrate is moved to a substrate rotation chamber and rotated therein, and then the substrate is transferred to a vapor deposition chamber and undergoes vapor deposition. In this vapor deposition apparatus, the substrate undergoes pre-alignment in the preparation chamber, cleaning in the plasma processing chamber, and rotation in the substrate rotation chamber. Then, the substrate is conveyed to the first vapor deposition chamber. After alignment between the substrate and a mask is performed in the first vapor deposition chamber, vapor deposition is performed on the substrate. Thereafter, the substrate is conveyed to the second vapor deposition chamber and undergoes further vapor deposition. By repeating the processing as described above, a plurality of layers are formed on the substrate.

In a method in which a substrate is sequentially conveyed to a plurality of film forming chambers to form films, positional shifts of the substrate can be accumulated in each film forming chamber. In PTL 1, such accumulation of positional shifts of the substrate is not considered.

### SUMMARY OF THE INVENTION

The present invention provides a technique advantageous in reducing accumulation of positional shifts of a substrate.

An aspect of the present invention provides a substrate processing apparatus, comprising: a film forming chamber in which a film is formed on a substrate; and a movable member configured to support a mask or both the mask and the substrate in an internal space of the film forming chamber and be movable, wherein before the film is formed on the substrate, in a state in which the substrate conveyed to the internal space of the film forming chamber by a substrate conveying mechanism is separated from the mask supported by the movable member, the movable member moves so as to reduce an alignment error between the substrate and the mask and then supports the substrate, and the movable member moves to a predetermined position after the substrate is supported by the movable member and before the substrate is taken out from the film forming chamber by the substrate conveying mechanism.

Further features of the present invention will become apparent from the following description of exemplary embodiments with reference to the attached drawings.

### BRIEF DESCRIPTION OF THE DRAWINGS

FIG. 1 is a view showing the arrangement of a substrate processing apparatus according to an embodiment;

FIGS. 2A to 2C are views showing processing performed in a processing chamber configured as a film forming chamber;

FIGS. 3A to 3C are views showing processing performed in the processing chamber configured as the film forming chamber;

FIGS. 4A and 4B are views showing processing performed in the processing chamber configured as the film forming chamber;

FIGS. 5A and 5B are views showing processing performed in the processing chamber configured as the film forming chamber;

FIG. 6 is a table exemplarily showing results in the first example;

FIG. 7 is a table exemplarily showing results in the second example;

FIG. 8 is a table exemplarily showing results in the third example;

FIG. 9 is a table exemplarily showing results in the third example;

FIG. 10 is a table exemplarily showing results in the third example; and

FIG. 11 is a table exemplarily showing results in a comparative example.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the manufacture of a display device including an array of light emitting elements such as organic light emitting elements, a mask vapor deposition method is known as a method of forming a fine pattern. In the mask vapor deposition method, after alignment between a substrate and a mask is performed, a vapor deposition material (for example, an organic material or an electrode material) is deposited at a target position on the substrate through the opening of the mask. In order to deposit the vapor deposition material at the target position on the substrate with high accuracy, alignment between the substrate and the mask is performed.

As the alignment method, there are a method of moving a substrate and a substrate supporting mechanism supporting the substrate before the substrate is placing on a mask, and a method of moving a mask stage supporting the mask. The former method has an advantage that the number of steps is small. However, in the former method, it is necessary to increase the contact part between an arm for supporting the substrate and the substrate to stably hold the substrate while moving. This has drawbacks that the range in which foreign matter adheres to the substrate can be expanded, and scratches are readily generated on the substrate due to vibration during movement. In the latter method, since there is no need to move the substrate during a period after loading the substrate into the film forming chamber until placing the substrate on the mask, the size of the contact part between the arm of the substrate supporting mechanism and the substrate can be minimized to allow the substrate to rest. Further, in the latter method, no scratch is generated on the substrate in the contact part between the substrate and the arm. In addition, the fact that there is no need to move the substrate is suitable for processing a large substrate.

Substrate processing apparatuses for forming a plurality films on a substrate include an in-line type and a cluster type. The in-line type is suitable for processing a large substrate, and the cluster type can cope with applications from small to large substrate sizes. An organic light emitting element includes a plurality of functional layers, so that the cluster type substrate processing apparatus can include a plurality of film forming chambers corresponding to the plurality of functional layers. Other than the film forming chambers, a plurality of processing chambers such as a preparation chamber, a pre-processing chamber, a conveyance chamber, a relay chamber, and a substrate stock chamber can also be included. A substrate can be conveyed between these processing chambers by a substrate conveying mechanism. When the substrate is conveyed many times between the plurality of processing chambers by the substrate conveying mechanism, minor positional shifts due to a positional shift during conveyance, a positional shift during transfer, a positional shift due to alignment in the film forming chamber, and the like can be accumulated between the reference position of the hand of the substrate conveying mechanism and the reference position of the substrate 111. Accordingly, as the number of processing chambers increases, the positional shift between the reference position of the substrate and the reference position of the hand of the substrate conveying mechanism can increase in the latter half of the film formation process. As a result, in the worst case, the substrate may protrude from the substrate holding portion of the hand of the substrate conveying mechanism and tilt, or the substrate may fall from the hand. Further, even when the substrate does not tilt or fall, if the reference position of the substrate largely shifts from the reference position of the hand, the positional shift between the reference position of the substrate and the reference position of the processing chamber can be large. Therefore, realignment or the positional shift beyond an assumed range may occur, which can cause the film formation process to be stopped. For the reasons described above, it is necessary to eliminate accumulation of positional shifts.

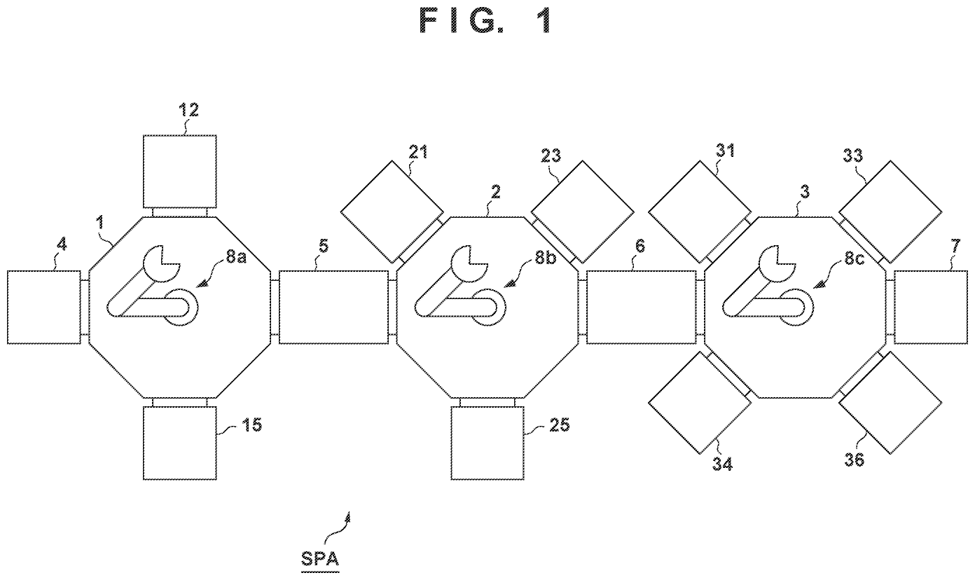

FIG. 1 shows the arrangement of a substrate processing apparatus SPA according to an embodiment. The substrate processing apparatus SPA includes, for example, a preparation chamber (load lock chamber) 4, a take-out chamber (unload lock chamber) 7, one or a plurality of processing chambers 12, 15, 21, 23, 25, 31, 33, 34, and 36, and one or a plurality of conveyance chambers 1, 2, and 3. The plurality of processing chambers 12, 15, 21, 23, 25, 31, 33, 34, and 36 can include at least one film forming chamber. In one example, all of the plurality of processing chambers 12, 15, 21, 23, 25, 31, 33, 34, and 36 are film forming chambers. Each of the processing chambers 12, 15, 21, 23, 25, 31, 33, 34, and 36 is a chamber in which processing (for example, film formation, cleaning, etching, ion beam irradiation, annealing, rotation, or the like) is performed on a substrate. The film forming chamber is a chamber in which film formation (formation of a film) is performed on a substrate. Film formation can include, for example, vapor deposition (PVD or CVD) in a reduced pressure environment. PVD can include, for example, resistance heating vapor deposition, sputtering, and the like. CVD can include, for example, plasma CVD, epitaxial CVD, and the like.

Substrate conveying mechanisms 8a, 8b, and 8c can be arranged in the conveyance chambers 1, 2, and 3, respectively. In the following description, when the substrate conveying mechanisms 8a, 8b, and 8c are described without being distinguished from each other, they will be described as the substrate conveying mechanisms 8. The substrate conveying mechanisms 8a, 8b, and 8c can be, for example, SCARA robots. The substrate processing apparatus SPA can include relay chambers 5 and 6 arranged between the plurality of conveyance chambers 1, 2, and 3. In one example, the conveyance chamber 1 can be arranged between the preparation chamber 4 and the relay chamber 5, the conveyance chamber 2 can be arranged between the relay chamber 5 and the relay chamber 6, and the conveyance chamber 3 can be arranged between the relay chamber 6 and the take-out chamber 7. Further, in one example, the processing chambers 12 and 15 can be connected to the conveyance chamber 1, the processing chambers 21, 23 and 25 can be connected to the conveyance chamber 2, and the processing chambers 31, 33, 34, and 36 can be connected to the conveyance chamber 3. Each of the conveyance chambers 1, 2, and 3, the relay chambers 5 and 6, and the processing chambers 12, 15, 21, 23, 25, 31, 33, 34, and 36 can be maintained in a reduced pressure environment.

A substrate is conveyed into the preparation chamber 4 opened to the atmosphere by a conveying mechanism (not shown) or the like, and then the pressure in the preparation chamber 4 can be reduced. Thereafter, the substrate can be conveyed from the preparation chamber 4 to the conveyance chamber 1 by the substrate conveying mechanism 8a via a valve provided between the preparation chamber 4 and the conveyance chamber 1. Then, the substrate can be conveyed to the processing chamber 12 by the substrate conveying mechanism 8a and processed in the processing chamber 12. After that, the substrate can be conveyed to the processing chamber 15 by the substrate conveying mechanism 8a and processed in the processing chamber 15. Thereafter, the substrate can be taken out from the processing chamber 15 by the substrate conveying mechanism 8a, conveyed to the relay chamber 5, and conveyed to the conveyance chamber 2 by the substrate conveying mechanism 8b. After that, a substrate 110 can be processed in the processing chambers 21, 23, and 25 connected to the conveyance chamber 2, conveyed to the conveyance chamber 3 via the relay chamber 6, and processed in the processing chambers 31, 33, 34, and 36 connected to the conveyance chamber 3. Then, the substrate is conveyed to the take-out chamber 7 by the substrate conveying mechanism 8c, and taken out from the take-out chamber 7 after the take-out chamber 7 is opened to the atmosphere.

In the following description, it is assumed that all of the processing chambers 12, 15, 21, 23, 25, 31, 33, 34, and 36 are configured as film forming chambers, and alignment between a substrate and a mask and film formation on the substrate via the opening of the mask are performed in these film forming chambers. However, processing other than film formation may be performed in at least one of the processing chambers 12, 15, 21, 23, 25, 31, 33, 34, and 36.

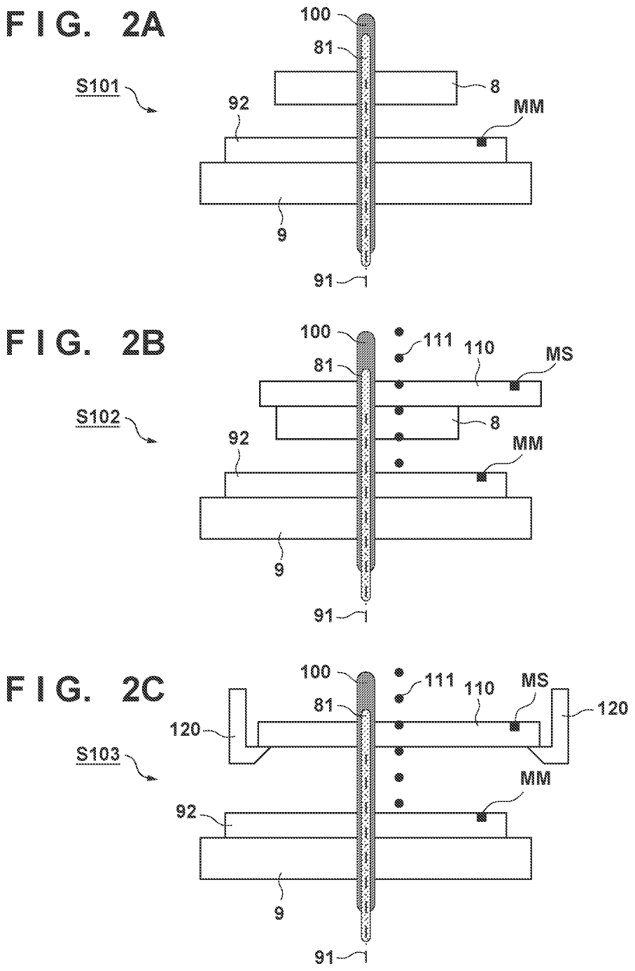

FIGS. 2A to 5B schematically show processing performed in each of the processing chambers 12, 15, 21, 23, 25, 31, 33, 34, and 36 configured as the film forming chambers. A movable member (movable stage) 9, a substrate supporting mechanism 120, and a detector 130 can be arranged in the internal space of each processing chamber configured as the film forming chamber. The processing performed in each processing chamber can include steps S101 to S110. Note that for illustrative simplicity, illustration of the substrate supporting mechanism 120 and the detector 130 are omitted in some steps.

The movable member 9 can support a mask 92 in the internal space of the processing chamber configured as the film forming chamber, or can support both the mask 92 and the substrate 110 in a stacked state. The movable member 9 is configured to be movable, and driven by a driving mechanism (not shown). The mask 92 limits a region in which a film (for example, a functional layer) is formed on the substrate 110. The substrate supporting mechanism 120 can support or hold the substrate 110 conveyed to the internal space of the processing chamber by the substrate conveying mechanism 8. The substrate supporting mechanism 120 may be understood as a holding member that holds the substrate 110. The detector 130 can detect an alignment error between the substrate 110 and the mask 92 in a state in which the substrate 110 conveyed to the internal space of the processing chamber by the substrate conveying mechanism 8 is separated from the mask 92 supported by the movable member 9. The detector 130 can detect the alignment error between the substrate 110 and the mask 92 based on the relative position between a mark MS provided on the substrate 110 and a mark MM provided on the mask 92.

In one example, the substrate processing apparatus SPA is advantageous in manufacturing a display device including an array of organic light emitting elements, and a plurality of films can be formed on a substrate via the openings of masks corresponding to the respective films.

First, in the teaching step (S101) shown in FIG. 2A, teaching for matching a reference axis 81 of the hand of the substrate conveying mechanism 8 with a reference axis 91 of the movable member 9 can be performed. Here, the reference axis 81 of the hand of the substrate conveying mechanism 8 means an axis passing through the reference position (origin) of the hand, and the reference axis 91 of the movable member 9 means an axis passing through the reference position (origin) of the movable member 9. The teaching can be performed so as to match the reference axis 81 of the hand of the substrate conveying mechanism 8 with a reference axis 100 of the processing chamber. The teaching can include a step of acquiring a control parameter value of the substrate conveying mechanism 8 required to match the reference axis 81 of the hand of the substrate conveying mechanism 8 with the reference axis 100 of the processing chamber.

Next, in the first conveying step (S102) shown in FIG. 2B, the substrate 110 can be conveyed to the internal space of the processing chamber by the substrate conveying mechanism 8. At this time, the substrate conveying mechanism 8 can move the substrate 110 (hand) so as to match the reference axis 81 with the reference axis 100 of the processing chamber and the reference axis 91 of the movable member 9. With this operation, the mark MM of the mask 92 and the mark MS of the substrate 110 can usually enter the field of view of the detector 130.

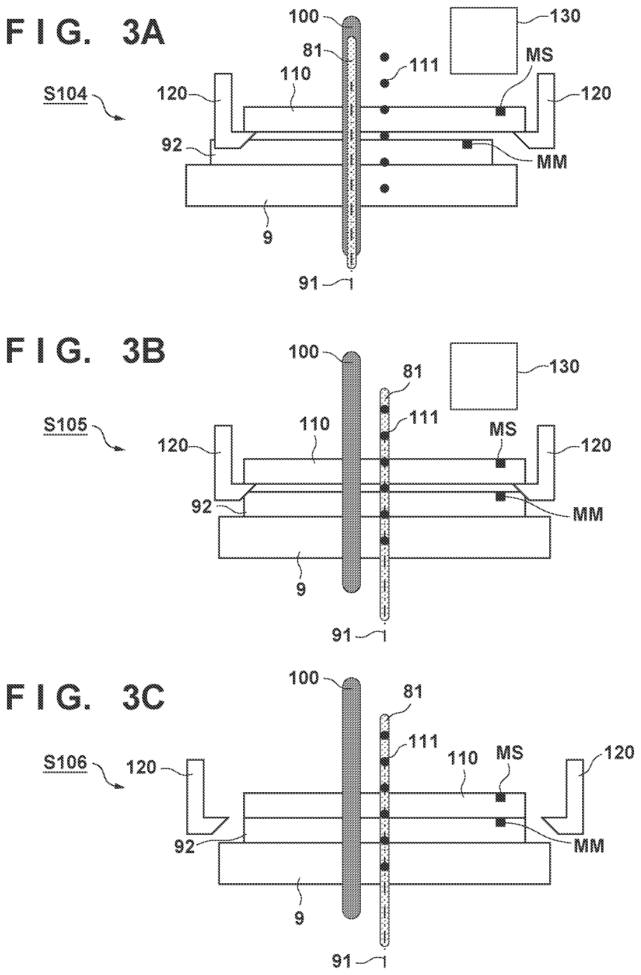

Next, in the receiving step (S103) shown in FIG. 2C, the substrate supporting mechanism 120 receives and supports the substrate 110. Then, in the alignment step (S104, S105, and S106) shown in FIGS. 3A to 3C, alignment between the mask 92 and the substrate 110 can be performed. This can be performed, in a state in which the substrate 110 conveyed to the internal space of the processing chamber by the substrate conveying mechanism 8 is separated from the mask 92 supported by the movable member 9, by the movable member 9 moving so as to reduce the alignment error between the substrate 110 and the mask 92. More specifically, the alignment can be performed, for example, as follows.

First, in the detection step (S104) shown in FIG. 3A, the detector 130 can detect the alignment error between the substrate 110 and the mask 92. Detection of the alignment error by the detector 130 can be performed in a state in which the substrate 110 supported by the substrate supporting mechanism 120 is separated from the mask 92 supported by the movable member 9. Detection of the alignment error may be performed not in a state in which the substrate 110 is supported by the substrate supporting mechanism 120 but, for example, in a state in which the substrate 110 is supported by the substrate conveying mechanism 8 as shown in FIG. 2B. Here, for example, in a state in which the mark MS and the mark MM shown in FIG. 3A are matched with each other in horizontal position (position in a direction along the surface of the substrate or the mask), the alignment error is evaluated as 0. Further, in a state in which the mark MS and the mark MM shown in FIG. 3A are shifted from each other in horizontal position by Δ, the alignment error can be evaluated as Δ. Then, in the first moving step (S105) shown in FIG. 3B, the movable member 9 supporting the mask 92 can move so as to reduce the alignment error detected by the detector 130. In the first moving step, the substrate 110 or the mask 92 may be moved, in a state in which the substrate 110 is separated from the mask 92, so as to reduce the alignment error between the substrate 110 and the mask 92.

Next, in the supporting step (S106) shown in FIG. 3C, the substrate 110 supported by the substrate supporting mechanism 120 can be placed on the mask 92 supported by the movable member 9. Thus, the mask 92 and the substrate 110 are supported by the movable member 9 in a stacked state. With this operation, the alignment between the substrate 110 and the mask 92 can be completed. The supporting step (S106) can be performed in a state in which the pressure in the internal space of the film forming chamber is reduced.

Here, in the state shown in FIG. 3C, the reference axis 91 of the movable member 9 is shifted from the reference axis 100 of the processing chamber. The alignment between the substrate 110 and the mask 92 may be performed by aligning the substrate 110 with the movable member 9 in a state in which the position of the mask 92 with respect to the movable member 9 is ensured. This alignment can be performed by detecting the relative position between a reference mark provided on the movable member 9 and the mark MS of the substrate 110 by the detector 130, and moving the movable member 9 based on the detection result. Alternatively, this alignment may be performed by abutting a member against the substrate 110 and further abutting the movable member 9 against this member, or by another method.

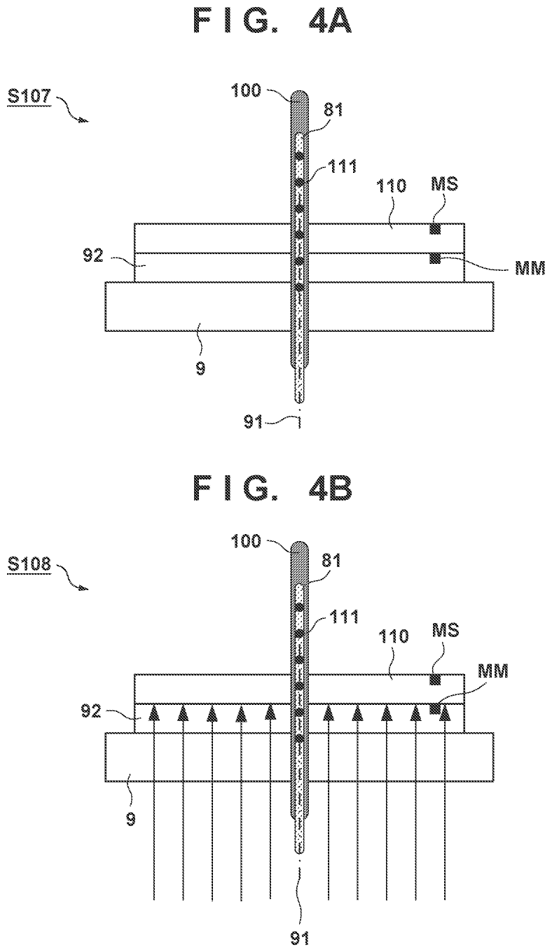

Next, in the second moving step (S107) shown in FIG. 4A, the movable member 9 moves so as to match the reference axis 91 of the movable member 9 with the reference axis 100 (predetermined position) of the processing chamber. In a simpler expression, this operation can be understood as an operation in which the movable member 9 moves to the reference axis 100 (predetermined position) of the processing chamber. Then, in the film formation step (S108) shown in FIG. 4B, a film can be formed on the substrate 110 via the opening of the mask 92 in a state in which the pressure in the internal space of the film forming chamber is reduced. The film formation can be performed on the substrate 110 while rotating the substrate 110. Alternatively, the film formation may be performed on the substrate 110 while rotating the substrate 110.

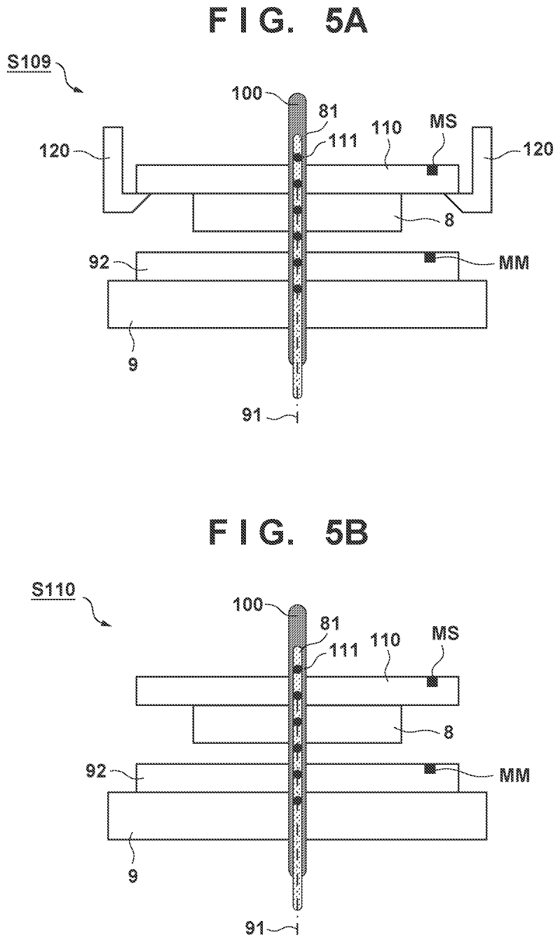

Next, in the transfer step (S109) shown in FIG. 5A, the substrate 110 can be supported by the substrate supporting mechanism 120, separated from the mask 92, and held by the hand of the substrate conveying mechanism 8 arranged at the reference axis 81. Then, in the step (S110) shown in FIG. 5B, the substrate 110 held by the hand of the substrate conveying mechanism 8 can be conveyed from the internal space of the processing chamber to the outer space.

In the example described above, the movable member 9 moves to the reference axis 100 (predetermined position) in the second moving step shown in FIG. 4A and after that, a film is formed on the substrate 110 in the step shown in FIG. 4B. That is, in the example described above, the movable member 9 moves to the reference axis 100 (predetermined position) before a film is formed on the substrate 110. Alternatively, the movable member 9 may move to the reference axis 100 (predetermined position) after a film is formed on the substrate 110 in the film formation step shown in FIG. 4B. In this case, the movable member 9 can be understood as a positioning mechanism for performing alignment between the substrate and the mask 92 before a film is formed on the substrate conveyed to the internal space of the processing chamber by the substrate conveying mechanism 8, and positioning the substrate at a predetermined position after the film is formed on the substrate. Alternatively, the movable member 9 can be understood as a supporting member for supporting the mask 92, and the driving mechanism that drives the movable member 9 can be understood as a moving mechanism that changes the relative position between the mask 92 and the substrate 110 and a moving mechanism that moves the substrate 110 after a film (for example, a functional layer) is formed.

To summarize the above, the movable member 9 may move to the reference axis 100 (predetermined position) after the substrate 110 is supported by the movable member 9 and before the substrate 110 is taken out from the processing chamber by the substrate conveying mechanism 8. In addition, the movable member 9 may move to the reference axis 100 (predetermined position) before a film is formed on the substrate 110 or after a film is formed on the substrate 110. By performing processing (to be referred to as “position reset processing” hereinafter) of moving the moving member 9 to the reference axis 100 (predetermined position) before the substrate 110 is taken out from the processing chamber, the substrate 110 can be transferred to the substrate conveying mechanism 8 in a state in which the positional shift of the substrate 110 at the time of being conveyed to the processing chamber by the substrate conveying mechanism 8 is reduced. This can solve the problem that positional shifts are accumulated each time the substrate 110 is conveyed by the substrate conveying mechanism 8.

When the plurality of processing chambers used in the substrate processing apparatus SPA include a plurality of film forming chambers, the position reset processing can be performed in at least one of the plurality of film forming chambers. Alternatively, when the plurality of processing chambers used in the substrate processing apparatus SPA include a plurality of film forming chambers, the position reset processing can be performed in at least one film forming chamber among all the film forming chambers connected to one conveyance chamber. In the film forming chamber in which the position reset processing (second moving step S107) is not performed, the movable member 9 moves to a correction position in first moving step S105 so as to reduce the alignment error, and film formation step S108 can be performed in this state. Then, in the state in which the movable member 9 is arranged at the correction position, the substrate 110 can be taken out from the film forming chamber by the substrate conveying mechanism 8.

When all of the plurality of processing chambers used in the substrate processing apparatus SPA are the film forming chambers, the position reset processing can be performed in at least one of the plurality of processing chambers. Alternatively, when all of the plurality of processing chambers used in the substrate processing apparatus SPA are the film forming chambers, the position reset processing can be performed in at least one processing chamber among all the processing chambers connected to one conveyance chamber.

As a comparative example, accumulation of positional shifts in a case in which the operation of moving the movable member 9 to the reference axis 100 (predetermined position) before the substrate 110 is taken out from the processing chamber is not performed will be described below.

A positional shift can be generated when a substrate is conveyed to the preparation chamber 4. Further, in each processing chamber, positional shifts of the substrate can be generated when the substrate conveying mechanism 8a receives the substrate in the preparation chamber 4, when the substrate supporting mechanism 120 receives the substrate from the substrate conveying mechanism 8a, and when the substrate conveying mechanism 8a receives the substrate from the substrate supporting mechanism 120 after a film is formed. Furthermore, positional shifts of the substrate can also be generated when the substrate is passed from the substrate conveying mechanism 8a to the substrate conveying mechanism 8b in the relay chamber 5, and when the substrate is passed from the substrate conveying mechanism 8b to the substrate conveying mechanism 8c in the relay chamber 6. Therefore, in the comparative example, accumulation of positional shifts of the substrate can increase as the number of the processing chambers 12, 15, . . . increases, and as the number of the relay chambers 5 and 6 increases.

Here, assuming that a positional shift amount of the reference axis of the substrate from the reference axis of the processing chamber when the substrate is conveyed to the internal space of the nth processing chamber is aₙ, a positional shift amount Aₙ of the substrate conveyed to the internal space of the nth processing chamber via (n−1) processing chambers is expressed by equation (1):

$${A}_{n} = \sqrt{{a}_{1}^{2} + {a}_{2}^{2} + … + {a}_{n}^{2}} \qquad ( 1 )$$

where n is an integer equal to or larger than 1.

A positional shift of the substrate is represented by an x-axis coordinate value and a y-axis coordinate value as in equation (2). A positional shift can also be generated when the substrate is passed from the substrate conveying mechanism 8a to the substrate conveying mechanism 8b in the relay chamber 5.

At the reference position in the nth processing chamber, Aₙ(x, y)=(0, 0). Accordingly, in the comparative example, the substrate has the positional shift expressed by equation (2) in the nth processing chamber.

$${A}_{n} ( x , y ) = ( \sqrt{{x}_{1}^{2} + {x}_{2}^{2} + … + {x}_{n}^{2}} , \sqrt{{y}_{1}^{2} + {y}_{2}^{2} + … + {y}_{n}^{2}} ) \qquad ( 2 )$$

### EXAMPLES

Examples in each of which the above-described position reset processing in the processing apparatus SPA was applied will be exemplarily described below. In the examples described below, for the sake of simplicity, all the processing chambers to be used are the film forming chambers.

### First Example

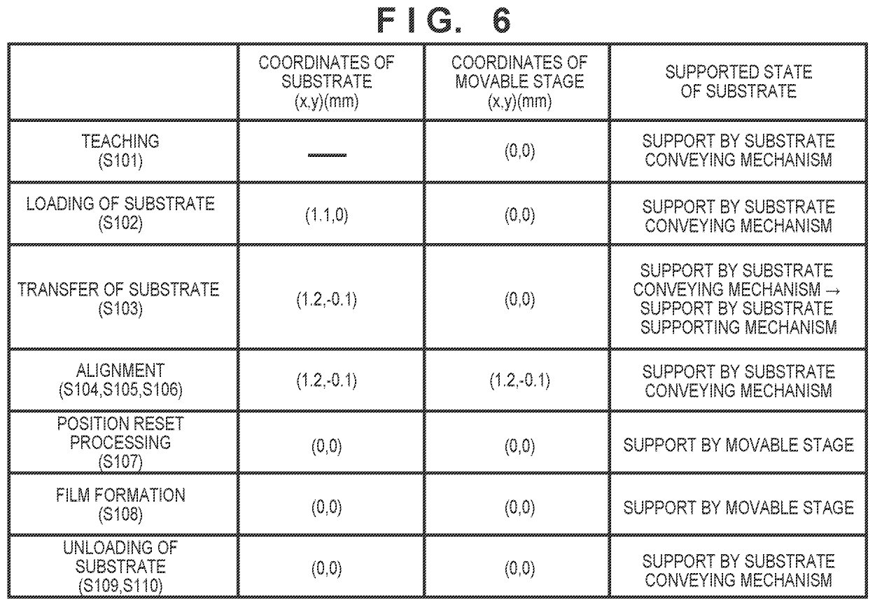

In the first example, steps S101 to S110 including the position reset processing (S107) were performed in each of the first processing chamber 12, the second processing chamber 15, the third processing chamber 21, the fourth processing chamber 23, the fifth processing chamber 25, the sixth processing chamber 31, the seventh processing chamber 33, the eighth processing chamber 34, and the ninth processing chamber 36. The processing on the substrate was performed in the order of the processing chambers 12, 15, 21, 23, 25, 31, 33, 34, and 36. FIG. 6 shows the coordinates of the substrate 110 and the coordinates of the movable member 9 measured in the first processing chamber 12 in the first example. Here, the coordinates of the substrate 110 indicate the shift amount of the reference position (center) of the substrate 110 from the reference axis 100 of the processing chamber 12, and the coordinates of the movable member 9 indicate the shift amount of the reference position (center) of the movable member 9 from the reference axis 100 of the processing chamber 12. The coordinates A₁(x, y) of the substrate at the time of unloading the substrate from the first processing chamber 12 were (0, 0). In addition, the coordinates Aₙ(x, y) of the substrate at the time of unloading the substrate from the nth processing chamber were (0, 0). Further, the coordinates A₉(x, y) of the substrate at the time of unloading the substrate from the ninth processing chamber were (0, 0). According to the first example, accumulation of positional shifts of the substrate did not occur.

### Second Example

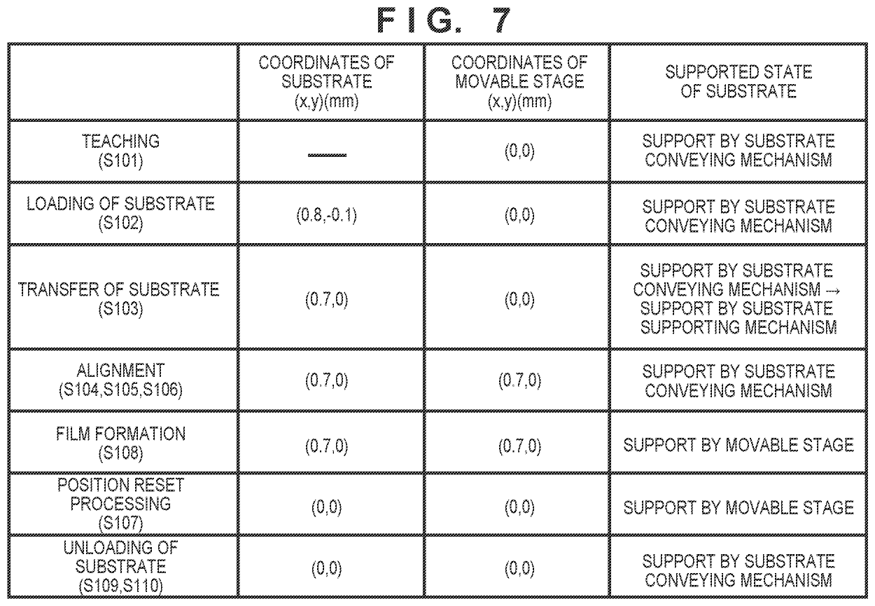

In the second example, the position reset processing (S107) and film formation (S108) in the first example were exchanged. In the second example, steps S101 to S110 including the position reset processing (S107) were performed in each of the first processing chamber 12, the second processing chamber 15, the third processing chamber 21, the fourth processing chamber 23, the fifth processing chamber 25, the sixth processing chamber 31, the seventh processing chamber 33, the eighth processing chamber 34, and the ninth processing chamber 36. The processing on the substrate was performed in the order of the processing chambers 12, 15, 21, 23, 25, 31, 33, 34, and 36. FIG. 7 shows the coordinates of the substrate 110 and the coordinates of the movable member 9 measured in the first processing chamber 12 in the second example.

### Third Example

In the third example, steps S101 to S110 including the position reset processing (S107) were performed in each of the second processing chamber 15 connected to the first conveyance chamber 1, the fourth processing chamber 23 connected to the second conveyance chamber 2, and the ninth processing chamber 36 connected to the third conveyance chamber 3. In the third example, only steps S101 to S106, S109, and S110 were performed in the other processing chambers.

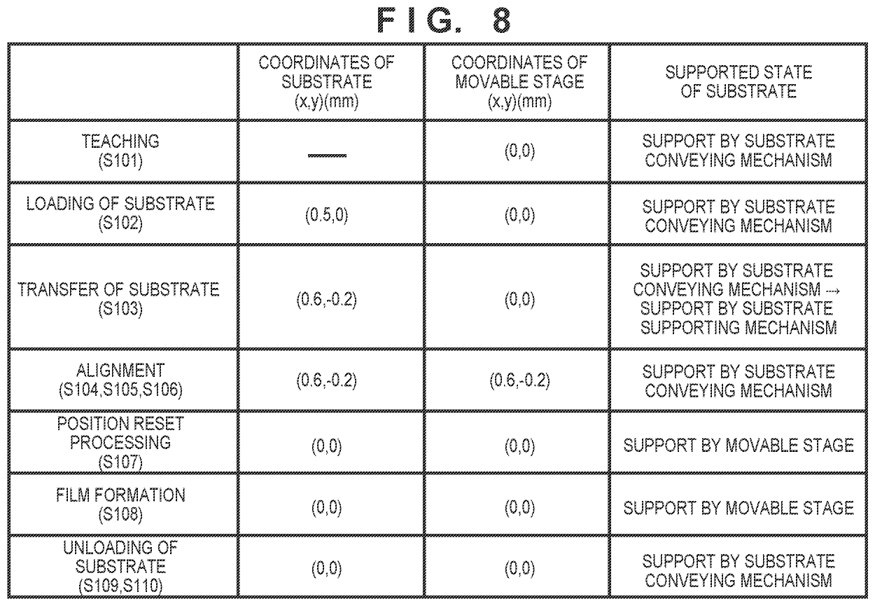

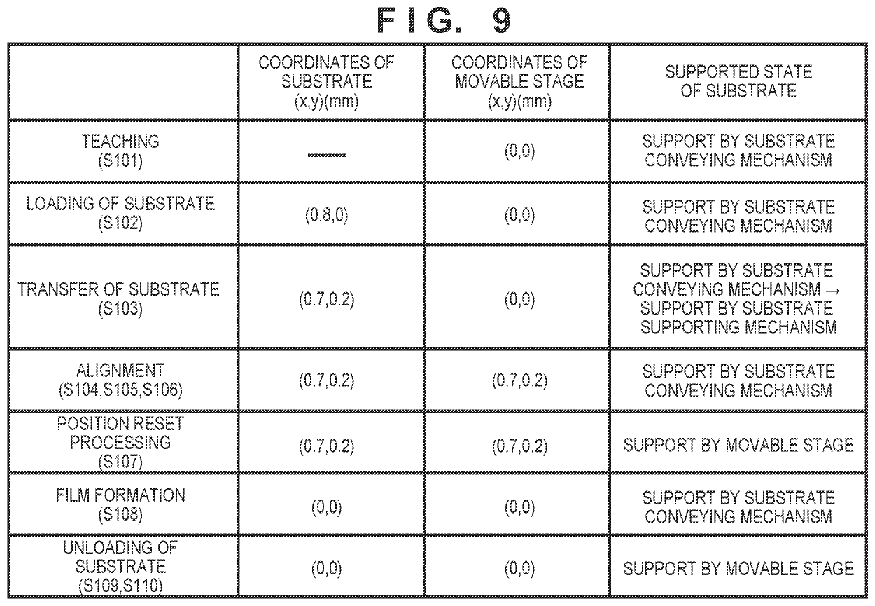

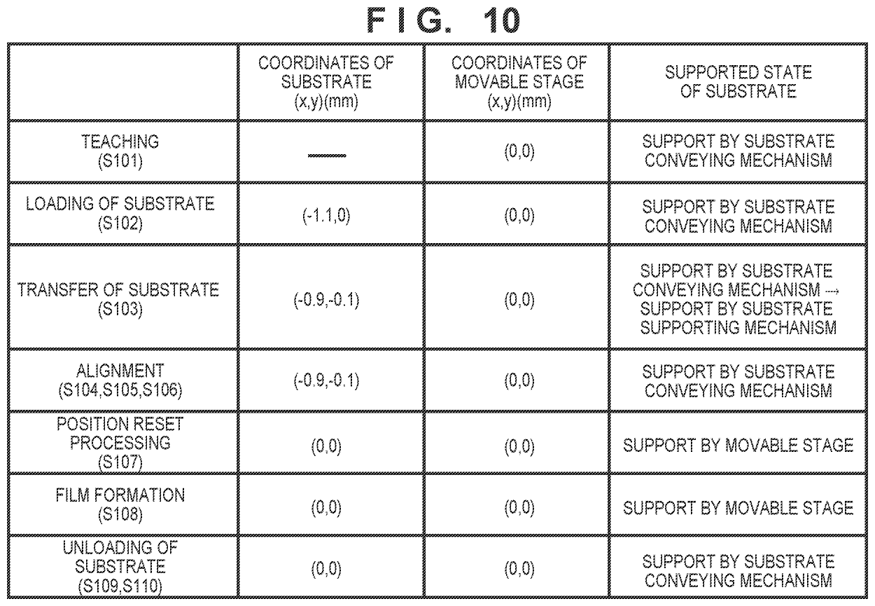

FIG. 8 shows the coordinates of the substrate 110 and the coordinates of the movable member 9 measured in the second processing chamber 15 in the third example. FIG. 9 shows the coordinates of the substrate 110 and the coordinates of the movable member 9 measured in the fourth processing chamber 23 in the third example. FIG. 10 shows the coordinates of the substrate 110 and the coordinates of the movable member 9 measured in the ninth processing chamber 36 in the third example. The coordinates A₂(x, y) of the substrate at the time of unloading the substrate from the second processing chamber 15 were (0, 0). The coordinates A₄(x, y) of the substrate at the time of unloading the substrate from the fourth processing chamber 23 were (0, 0). The coordinates A₉(x, y) of the substrate at the time of unloading the substrate from the ninth processing chamber 36 were (0, 0). According to the third example, accumulation of positional shifts of the substrate did not occur.

### COMPARATIVE EXAMPLE

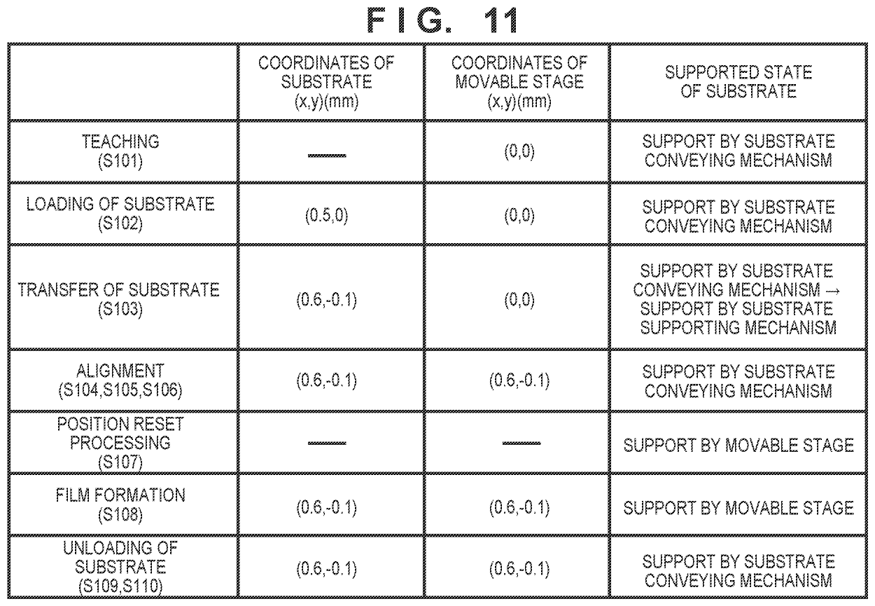

The comparative example is similar to the first example except that the position reset processing (S107) was not performed in any of the processing chambers. FIG. 11 shows the coordinates of the substrate 110 and the coordinates of the movable member 9 measured in the first processing chamber 12 in the comparative example. The coordinates A₁(x, y) of the substrate at the time of unloading the substrate from the first processing chamber 12 were (0.6,−0.1). The coordinates A₉(x, y) of the substrate at the time of unloading the substrate from the ninth processing chamber 36 were (1.8, −0.3). It can be found that accumulation of positional shifts of the substrate has occurred in the comparative example.

According to the present invention, a technique advantageous in reducing accumulation of positional shifts of a substrate is provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A substrate processing method comprising:
moving, in an internal space of a film forming chamber, a substrate or a mask that limits a region in which a film is formed on the substrate so as to reduce an alignment error between the substrate and the mask;
supporting, after the moving the substrate or the mask, the mask and the substrate in a stacked state by a movable member in a state in which a pressure in the internal space is reduced;
forming a film on the substrate via the mask after the supporting; and
conveying the substrate from the internal space of the film forming chamber to an outside after the forming,
wherein the method further comprises moving, between the supporting and the forming or between the forming and the conveying, the movable member supporting the substrate to a predetermined position different from a position in a preceding process.

2. The method according to claim 1, wherein the moving the substrate or the mask includes causing the movable member to move in a state in which the substrate is supported by a substrate supporting mechanism.

3. The method according to claim 1, further comprising conveying, before the moving the substrate or the mask, the substrate into the film forming chamber by a substrate conveying mechanism so as to match a reference position of a hand of the substrate conveying mechanism with the predetermined position.

4. The method according to claim 1, wherein in the moving the substrate or the mask, the substrate is separated from the mask.

5. The method according to claim 1, wherein of a process between the supporting and the forming and a process between the forming and the conveying the substrate to the outside, the moving the movable member to the predetermined position is performed only in the process between the forming and the conveying the substrate to the outside.
